(19) United States
(12) Patent Application Publication
(10) Pub. No.: US 2018/0215284 A1
(43) Pub. Date: Aug. 2, 2018

(54) ELECTRIC CAR CONTROL DEVICE

(71) Applicants: Kabushiki Kaisha Toshiba, Minato-ku (JP); Toshiba Infrastructure Systems & Solutions Corporation, Kawasaki-shi (JP)

(72) Inventors: Hiroaki OTANI, Fuchu (JP); Tomoyuki MAKINO, Iruma (JP)

(73) Assignees: Kabushiki Kaisha Toshiba, Minato-ku (JP); Toshiba Infrastructure Systems & Solutions Corporation, Kawasaki-shi (JP)

(21) Appl. No.: 15/914,557

(22) Filed: Mar. 7, 2018

Related U.S. Application Data
(63) Continuation of application No. PCT/JP2016/076417, filed on Sep. 8, 2016.

(30) Foreign Application Priority Data
Sep. 9, 2015 (JP) 2015-177509

(51) Int. Cl. B60L 15/00; B61C 17/00; H01L 23/467

(52) U.S. Cl. CPC B60L 15/007; B61C 17/00; H01L 23/467; H02M 7/537; B60L 2210/30; B60L 2210/40; B60L 2200/30

(57) ABSTRACT

An electric car control device according to the embodiments includes a housing, a converter, an inverter, a converter cooling unit, and an inverter cooling unit. The housing is provided under a floor of a car body. The converter is housed in the housing, is connected to an alternating current power source, and converts supplied alternating current power into direct current power. The inverter is housed in the housing, and converts the direct current power into alternating current power for driving a motor. The converter cooling unit is disposed on a bottom surface side of the housing and cools the converter. The inverter cooling unit is disposed on a bottom surface side of the housing and cools the inverter.

### CROSS-REFERENCE TO RELATED APPLICATION

This is a Continuation Application of International Application No. PCT/JP2016/076417, filed on Sep. 8, 2016, which claims priority to Japanese Patent Application No. 2015-177509, filed on Sep. 9, 2015, and the entire contents of all of the aforementioned applications are incorporated herein by reference.

### FIELD

Embodiments described herein relate generally to an electric car control device.

### BACKGROUND

Alternating current power is provided to a railcar from an overhead line via a pantograph provided on a roof of the car body. This alternating current power is supplied to an electric motor via an electric car control device provided under a floor of the car body. The electric car control device includes a converter for converting alternating current power into direct current power, and an inverter for converting direct current power output from the converter into alternating current power for driving an electric motor.

Here, in the electric car control device, a cooling unit such as cooling fins for radiating heat generated by a converter or an inverter is provided. As a result, heat loss of a converter or an inverter is reduced.

Incidentally, when cooling fins are disposed on a bottom surface side of an electric car control device, it is known that a sufficient air volume cannot be obtained when a railcar travels at a low speed and a cooling capacity of the cooling fins is lowered. On the other hand, when cooling fins are disposed on a side surface side of an electric car control device, it is known that an air volume is not stable when a railcar travels at a high speed as compared with the case in which the cooling fins are disposed on the bottom surface side.

Therefore, disposing cooling fins across both sides of the bottom surface side and the side surface side of an electric car control device to cool both of a converter and an inverter can be considered.

However, if cooling fins are designed to have a sufficient capacity to cool both a converter and an inverter, the cooling fins may be increased in size.

In addition, a converter and an inverter are integrated via cooling fins, and thereby there may be a big burden of maintenance even if any one of the converter, inverter, and cooling fins needs maintenance.

### BRIEF DESCRIPTION OF THE DRAWINGS

FIG. 1 is a schematic configuration diagram which shows an electric car control device according to a first embodiment.

FIG. 2 is a block diagram which shows the electric car control device according to the first embodiment.

FIG. 3 is a graph which shows a change in a current value of a converter and an inverter according to the first embodiment.

FIG. 4 is a schematic configuration diagram which shows an electric car control device according to a second embodiment.

FIG. 5 is a schematic configuration diagram which shows an electric car control device according to a third embodiment.

FIG. 6 is a schematic configuration diagram which shows an electric car control device according to a fourth embodiment.

FIG. 7 is a schematic configuration diagram which shows an electric car control device in a modified example of the fourth embodiment.

### DETAILED DESCRIPTION

An electric car control device according to embodiments includes a housing, a converter, an inverter, a converter cooling unit, and an inverter cooling unit. The housing is provided under a floor of a car body. The converter is housed in the housing, is connected to an alternating current power source, and converts supplied alternating current power into direct current power. The inverter is housed in the housing, and converts direct current power into alternating current power for driving a motor. The converter cooling unit is disposed on a bottom surface side of the housing and cools the converter. The inverter cooling unit is disposed on a bottom surface of the housing and cools the inverter.

Hereinafter, an electric car control device according to embodiments will be described with reference to the drawings.

### First Embodiment

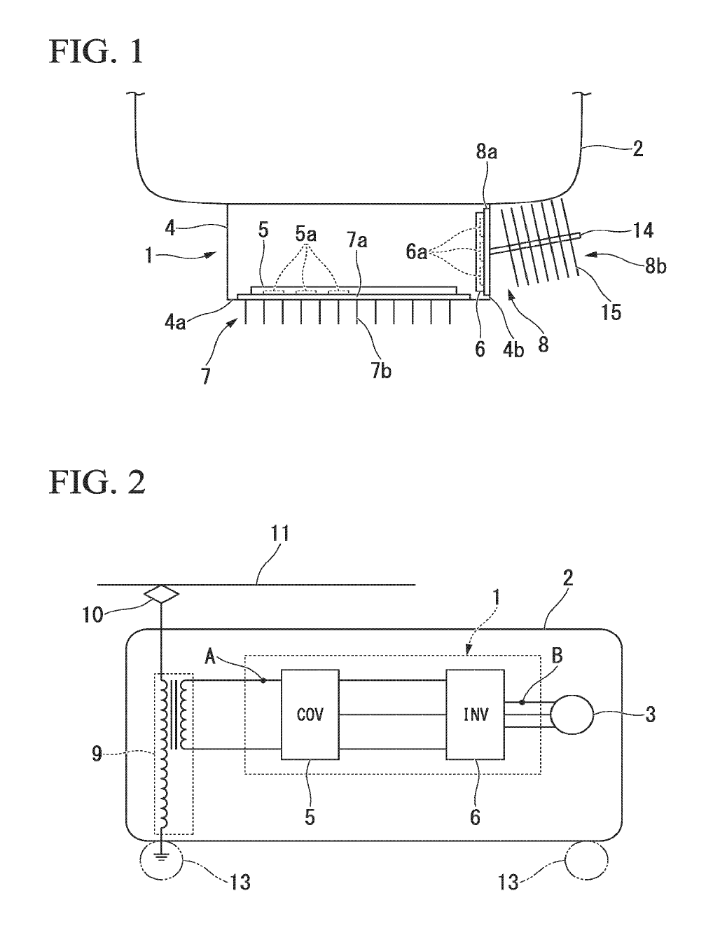

FIG. 1 is a schematic configuration diagram of an electric car control device 1, and FIG. 2 is a block diagram of the electric car control device 1.

As shown in FIGS. 1 and 2, the electric car control device 1 performs, for example, drive control of an electric motor 3 provided in a car body 2 of a railcar. The electric car control device 1 includes a box-shaped housing 4 provided under a floor of the car body 2, a converter 5 provided in the housing 4, an inverter 6, a converter cooling unit 7 for cooling the converter 5, and an inverter cooling unit 8 for cooling the inverter 6.

In addition, the electric car control device 1 is connected to an overhead line 11 via a main transformer (transformer) 9 and a pantograph 10. The pantograph 10 collects alternating current power which is supplied to the overhead line 11 and is connected to a ground point 12 via the main transformer 9. As the ground point 12, for example, a wheel 13 is used.

The converter 5 converts alternating current power supplied via the main transformer 9 into direct current power. The converter 5 is disposed on a bottom surface 4a of the housing 4.

On the other hand, the inverter 6 converts the direct current power converted by the converter 5 into alternating current power for driving the electric motor 3, and supplies the power to the electric motor 3. The inverter 6 is disposed on a side surface 4b of the housing 4.

The converter cooling unit 7 is disposed on the bottom surface 4a of the housing 4 so as to correspond to the converter 5. The converter cooling unit 7 is a so-called heat sink, and is constituted by a heat receiving plate 7a extending along the bottom surface 4a of the housing 4 and a fin-shaped heat radiating unit 7b extending downward from the heat receiving plate 7a. The converter 5 is provided to be in contact with the heat receiving plate 7a. Here, the converter 5 is provided so that a semiconductor element 5a constituting this converter 5 is in contact with the heat receiving plate 7a. The semiconductor element 5a is constituted by, for example, a switching element such as an insulated gate bipolar transistor (IGBT). The heat radiating unit 7b is formed so that fins extend in a front-rear direction of the car body 2. Accordingly, traveling air easily passes through the inside of the heat radiating unit 7b.

The inverter cooling unit 8 is disposed on the side surface 4b of the housing 4 to correspond to the inverter 6. The inverter cooling unit 8 is constituted by a heat receiving plate 8a extending along the side surface 4b of the housing 4, and a heat radiating unit 8b protruding outward from the heat receiving plate 8a toward the car body 2 in a vehicle width direction. The inverter 6 is provided to be in contact with the heat receiving plate 8a. Here, the inverter 6 is provided so that the semiconductor element 6a constituting this inverter 6 is in contact with the heat receiving plate 8a. The semiconductor element 6a is constituted by, for example, a switching element such as an insulated gate bipolar transistor (IGBT).

To describe the heat radiating unit 8b of the inverter cooling unit 8 in detail, the heat radiating unit 8b is constituted by a heat pipe 14 extending obliquely upward from the heat receiving plate 8a and a plurality of fins 15 provided on an outer peripheral surface of the heat pipe 14 and extending in a normal direction with respect to an extending direction of the heat pipe 14. The inside of the heat pipe 14 is filled with a hydraulic fluid for promoting heat exchange between the heat pipe 14 and the outside. For this reason, the heat pipe 14 is provided obliquely with respect to a horizontal direction so that the hydraulic fluid circulates in the heat pipe 14 normally.

With such a configuration, power is supplied to the electric motor 3 via the pantograph 10, the main transformer 9, and the electric car control device 1 from the overhead line 11, and the railcar travels at a desired speed according to a drive of the electric motor 3.

At this time, heat generated by the converter 5 of the electric car control device 1 is radiated via the converter cooling unit 7. As a result, the converter 5 is cooled. On the other hand, heat generated by the inverter 6 is radiated via the inverter cooling unit 8. As a result, the inverter 6 is cooled.

Here, since the converter cooling unit 7 is disposed on the bottom surface 4a of the housing 4, a cooling capacity is improved by obtaining a large air volume when the railcar travels at a high speed. On the other hand, since the inverter cooling unit 8 is disposed on the side surface 4b of the housing 4, it is possible to efficiently increase the cooling capacity using an ascending air current when the railcar travels at a low speed.

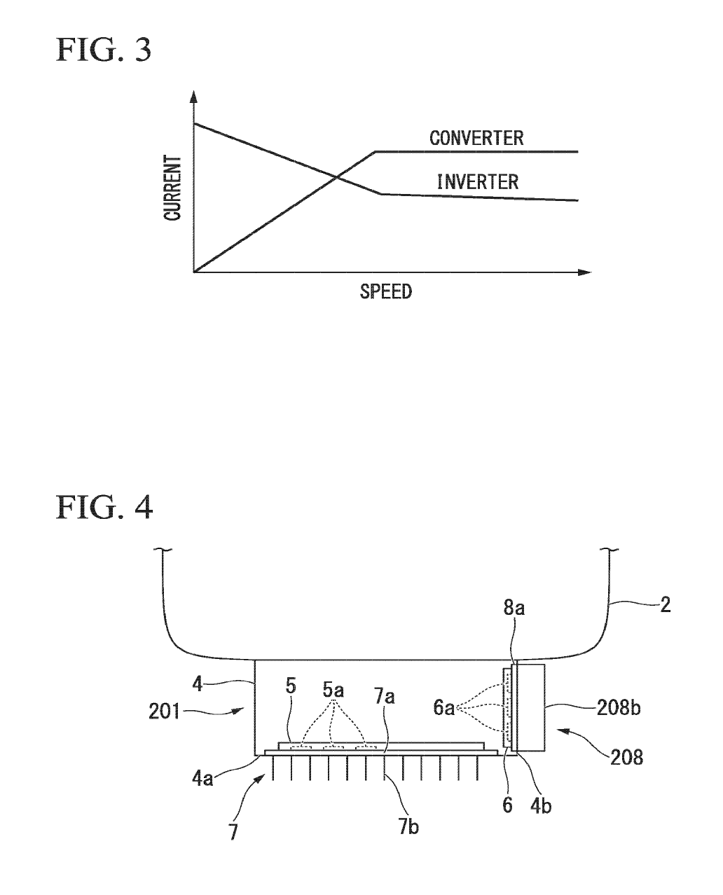

A load applied to the converter 5 and the inverter 6 changes as shown in FIG. 3 to be described below during the traveling of the railcar.

FIG. 3 is a graph which shows changes in current values of the converter 5 and the inverter 6 of the case in which the vertical axis represents a current value and the horizontal axis represents a traveling speed of the railcar. In FIG. 3, a current value of the converter 5 is a current value (a current value at a point A in FIG. 2) input into the converter 5. In addition, a current value of the inverter 6 is a current value (a current value at a point B in FIG. 2) output from the inverter 6 in FIG. 3.

As shown in the same drawing, since a large torque is required when the railcar starts traveling, a current value of the inverter 6 increases. Then, a required torque decreases as a traveling speed increases, and thus the current value of the inverter 6 gradually decreases accordingly. That is, the inverter 6 has a large load when the railcar travels at a low speed and has a small load when the railcar travels at a high speed.

On the other hand, a supply current gradually increases from the start of traveling in the converter 5. Then, since an amount of current supply increases when the railcar travels at a high speed, the current value of the converter 5 is maintained at a large value. That is, the converter 5 has a large load when the railcar travels at a high speed and has a small load when the railcar travels at a low speed.

Therefore, as shown in the first embodiment described above, the converter 5 and the converter cooling unit 7 are disposed on the bottom surface 4a of the housing 4, and thereby it is possible to efficiently cool the converter 5 when the railcar travels at a high speed with a large load of the converter 5. In addition, the inverter 6 and the inverter cooling unit 8 are disposed on the side surface 4b of the housing 4, and thereby it is possible to efficiently cool the inverter 6 when the railcar travels at a low speed with a large load of the inverter 6. Moreover, the converter cooling unit 7 may be formed in a size capable of cooling only the converter 5, and the inverter cooling unit 8 may be formed in a size capable of cooling only the inverter 6. In this manner, cooling objects of the respective cooling units 7 and 8 are divided and the converter 5 and the inverter 6 can be efficiently cooled, and thus the cooling units 7 and 8 can decrease in size as a whole.

In addition, the semiconductor element 6a constituting the inverter 6 is provided to be in contact with the heat receiving plate 8a of the inverter cooling unit 8. Here, the semiconductor element 6a generates a large amount of heat, and it is possible to more efficiently cool the inverter 6 and to decrease the inverter cooling unit 8 in size by bringing this semiconductor element 6a in a contact with the heat receiving plate 8a.

Furthermore, it is possible to easily maintain the respective components 5 to 8 by dividing the cooling unit into a cooling unit for the converter 5 (the converter cooling unit 7) and a cooling unit for the inverter 6 (the inverter cooling unit 8). That is, for example, when the converter 5 is maintained, it is sufficient to remove the converter 5 and the converter cooling unit 7 from the housing 4, and thus it is not necessary to deliberately remove the inverter 6 and the inverter cooling unit 8. For this reason, the respective units 5 to 8 can be easily maintained.

In addition, the respective components 5 to 8 are disposed on different surfaces of the housing 4 depending on a function such that the converter 5 and the converter cooling unit 7 are disposed on the bottom surface 4a of the housing 4 and the inverter 6 and the inverter cooling unit 8 are disposed on the side surface 4b of the housing 4. For this reason, for example, when one of the converter 5 and the inverter 6 is removed from the housing 4, the other does not become an obstacle and the maintainability can be further improved.

Furthermore, since the heat receiving plates 7a and 8a of the respective cooling units 7 and 8 are disposed on the bottom surface 4a and the side surface 4b of the housing 4, respectively, it is possible to increase a heat radiation property of the heat receiving plates 7a and 8b themselves. That is, the heat receiving plate 7a of the converter cooling unit 7 is easily affected by traveling air when the railcar travels at a high speed and can increase a heat radiation property at the time of high speed traveling. Moreover, the heat receiving plate 8a of the inverter cooling unit 8 is easily affected by the ascending air current when the railcar travels at a low speed, and can increase a heat radiation property at the time of low speed traveling.

### Second Embodiment

Next, a second embodiment will be described with reference to FIG. 4.

FIG. 4 is a schematic configuration diagram of an electric car control device 201 of the second embodiment, and corresponds to FIG. 1 described above. In the following description, the same constituents as those in the first embodiment will be given the same reference numerals and descriptions thereof will be omitted (the same applies to the following embodiments).

As shown in the same drawing, a difference between the first embodiment and the second embodiment is that the shapes of the inverter cooling unit 8 in the first embodiment and an inverter cooling unit 208 in the second embodiment are different.

More specifically, the inverter cooling unit 208 of the second embodiment is constituted by the heat receiving plate 8a and a fin-shaped heat radiating unit 208b which extends outward in a vehicle width direction of the car body 2 from the heat receiving plate 8a. The heat radiating unit 208b is formed such that fins extend in a vertical direction of the car body 2. As a result, the ascending air current easily passes through the inside of the heat radiating unit 7b.

Therefore, according to the second embodiment described above, it is possible to achieve the same effects as the first embodiment described above.

### Third Embodiment

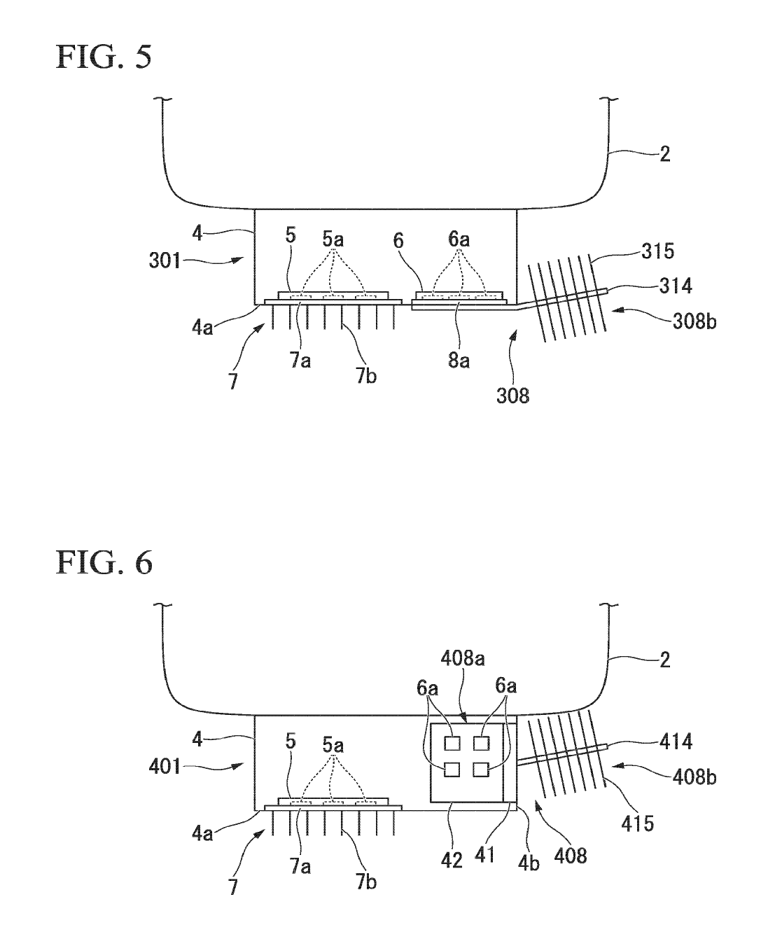

FIG. 5 is a schematic configuration diagram of an electric car control device 301 in the third embodiment, and corresponds to FIG. 1 described above.

As shown in the same drawing, a difference between the first embodiment and the third embodiment is that the position of the inverter 6 of the first embodiment is different from the position of the inverter 6 of the third embodiment.

More specifically, the inverter 6 of the third embodiment is disposed on the bottom surface 4a of the housing 4 in the same manner as the converter 5. On the other hand, in the inverter cooling unit 308, a heat radiating unit 308b in contact with the heat receiving plate 8a is constituted by a heat pipe 314 and a plurality of fins 315 provided on an outer peripheral surface of the heat pipe 314 and extending in a normal direction with respect to an extending direction of the heat pipe 314.

The heat pipe 314 is formed to extend outward in the vehicle width direction of the car body 2 from the bottom surface side of the heat receiving plate 8a, and thereafter to extend obliquely upward with respect to the horizontal direction.

Even with such a configuration, since most of the heat pipe 314 of the inverter cooling unit 308 and the heat radiating unit 308b are disposed on the side surface 4b side of the housing 4, it is possible to achieve the same effects as the first embodiment described above.

### Fourth Embodiment

FIG. 6 is a schematic configuration diagram of an electric car control device 401 in a fourth embodiment, and corresponds to FIG. 1 described above.

As shown in the same drawing, a difference between the first embodiment and the fourth embodiment is that the shape of the heat receiving plate 8a in the inverter cooling unit 8 of the first embodiment is different from the shape of a heat receiving plate 408a in an inverter cooling unit 408 of the fourth embodiment.

More specifically, the heat receiving plate 408a in the inverter cooling unit 408 of the fourth embodiment is constituted by a first plate 41 facing the side surface 4b of the housing 4 and a second plate 42 protruding toward the inside of the housing 4 from this first plate 41. The second plate 42 is formed to extend in the vehicle width direction and the vertical direction of the car body 2.

With such a configuration, the semiconductor element 6a of the inverter 6 is provided to be in contact with the second plate 42. With such a configuration, in addition to the same effects as in the first embodiment described above, it is possible to improve layout performance of the inverter 6 in the housing 4 and to achieve a decrease in a size of the inverter 6.

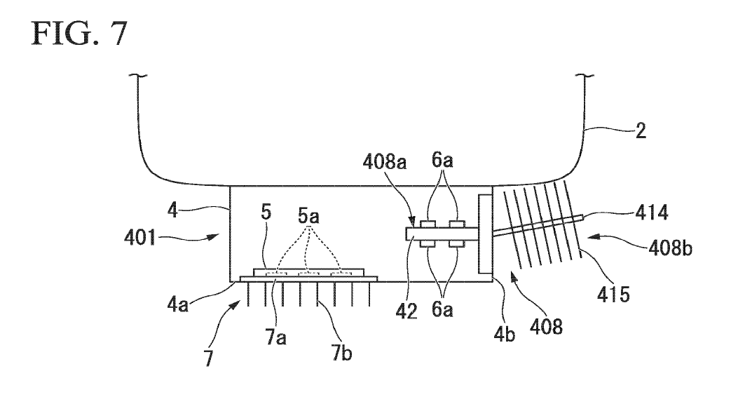

As shown in FIG. 7, the second plate 42 may be formed to extend in the vehicle width direction and the front-rear direction of the car body 2. With such a configuration, variations in the layout of the inverter 6 can be increased. For this reason, it is possible to improve the layout performance of the inverter 6 in the housing 4 and to achieve a decrease in the size of the inverter 6.

In the embodiments described above, a case in which the converter cooling unit 7 is constituted by the heat receiving plate 7a and the heat radiating unit 7b and a case in which the inverter cooling units 8 to 408 are constituted by the heat receiving plates 8a and 408a, and the heat radiating units 8b to 408b have been described. However, constituents of the converter cooling unit 7 and the inverter cooling units 8 to 408 are not limited to the embodiments described above, and may be any constituent capable of radiating heat generated by the converter 5 and the inverter 6.

For example, in the embodiments described above, a case in which the insides of the heat pipes 14 to 414 are filled with a hydraulic fluid has been described. However, the present invention is not limited thereto, and may be any configuration capable of transmitting heat.

In addition, in the description of the embodiments described above, one of the electric car control devices 1 to 401 is illustrated under the floor of the car body 2, but the present invention is not limited thereto, and a plurality of electric car control devices 1 to 401 can be provided under the floor of the car body 2 when necessary. Even in this case, the inverter cooling units 8 to 408 may be disposed on the side surface 4b side of the housing 4. More preferably, the inverter cooling units 8 to 408 may be disposed outward in the vehicle width direction of the car body 2.

According to at least one embodiment described above, it is possible to efficiently cool the converter 5 when the railcar travels at a high speed with a large load of the converter 5 by disposing the converter 5 and the converter cooling unit 7 on the bottom surface 4a of the housing 4. In addition, it is possible to efficiently cool the inverter 6 when the railcar travels at a low speed with a large load of the inverter 6 by disposing the inverter 6 and the inverter cooling units 8 to 408 on the side surface 4b of the housing 4. Moreover, the converter cooling unit 7 may be formed in a size capable of cooling only the converter 5 and the inverter cooling units 8 to 408 may be formed in sizes capable of cooling only the inverter 6. As described above, because cooling objects of the respective cooling units 7 and 8 are divided and the converter 5 and the inverter 6 can be efficiently cooled, it is possible to achieve a decrease in the sizes of the cooling units 7 and 8 to 408 as a whole.

In addition, the cooling unit is divided into a cooling unit for the converter 5 (the converter cooling unit 7) and a cooling unit for the inverter 6 (the inverter cooling units 8 to 408), and thereby the respective components 5 to 8 and 408 can be easily maintained. That is, for example, when the converter 5 is maintained, it is sufficient to remove the converter 5 and the converter cooling unit 7 from the housing 4, and thus it is not necessary to deliberately remove the inverter 6 and the inverter cooling unit 8. For this reason, the respective units 5 to 408 can be easily maintained.

Moreover, respective components 5 to 408 are disposed on different surfaces of the housing 4 depending on a function such that the converter 5 and the converter cooling unit 7 are disposed on the bottom surface 4a of the housing 4 and the inverter 6, and the inverter cooling units 8 to 408 are disposed on the side surface 4b of the housing 4. For this reason, for example, when one of the converter 5 and the inverter 6 is removed from the housing 4, the other does not become an obstacle and the maintainability can be further improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electric car control device comprising:
a housing which is provided under a floor of a car body;
a converter which is housed in the housing, is connected to an alternating current power source, and converts supplied alternating current power into direct current power;
an inverter which is housed in the housing and converts the direct current power into alternating current power for driving a motor;
a converter cooling unit which is disposed on a bottom surface side of the housing and cools the converter; and
an inverter cooling unit which is disposed on a side surface side of the housing and cools the inverter.

2. The electric car control device according claim 1,
wherein the inverter cooling unit includes
a heat receiving unit configured to receive heat from the inverter, and
a heat radiating unit configured to radiate heat transmitted from the heat receiving unit to the outside,
wherein a semiconductor element constituting the inverter is in contact with the heat receiving unit.

3. The electric car control device according to claim 2, wherein the heat receiving unit and the heat radiating unit are disposed on a side surface of the housing.

4. The electric car control device according to claim 1,
wherein the inverter is disposed on the side surface of the housing and the converter is disposed on a bottom surface of the housing.

5. The electric car control device according to claim 2,
wherein the inverter is disposed on the side surface of the housing and the converter is disposed on a bottom surface of the housing.

6. The electric car control device according to claim 3,
wherein the inverter is disposed on the side surface of the housing and the converter is disposed on a bottom surface of the housing.
